(19) United States
(12) Patent Application Publication
(10) Pub. No.: US 2025/0133945 A1
(43) Pub. Date: Apr. 24, 2025

(54) DISPLAY MODULE AND DISPLAY DEVICE

(71) Applicant: Yungu (Gu’an) Technology Co., Ltd., Langfang (CN)

(72) Inventor: Wentao YING, Langfang (CN)

(73) Assignee: Yungu (Gu’an) Technology Co., Ltd., Langfang (CN)

(21) Appl. No.: 19/010,155

(22) Filed: Jan. 5, 2025

(30) Foreign Application Priority Data
Feb. 23, 2024 (CN) 202410205504.0

(51) Int. Cl. H10K 59/80

(52) U.S. Cl. CPC H10K 59/8792; H10K 59/8731

(57) ABSTRACT

The present application discloses a display module and a display device. The display module includes a substrate, a light-emitting device layer and a shielding layer. The light-emitting device layer is arranged on a side of the substrate; the shielding layer is arranged on a side of the light-emitting device layer away from the substrate; and the shielding layer includes at least one shielding sublayer in a direction perpendicular to the substrate.

### CROSS REFERENCE TO RELATED APPLICATION

The present application claims priority to Chinese Patent Application No. 202410205504.0 filed on Feb. 23, 2024, which is incorporated herein by reference in its entirety.

### TECHNICAL FIELD

The present application relates to the technical field of displays, and in particular to a display module and a display device.

### BACKGROUND ART

Flat display modules such as liquid crystal display (LCD) panels, organic light emitting display (OLED) panels and display modules using light emitting diode (LED) devices are widely used in various consumer electronic products such as mobile phones, televisions, personal digital assistants, digital cameras, laptop computers and desktop computers thanks to their advantages such as high image quality, energy efficiency, slim design and a wide range of applications, and are thus predominate in display devices.

At present, how to reduce the reflection of external ambient light on the display modules has become an urgent problem to be solved.

### SUMMARY OF THE INVENTION

An objective of the present application is to provide a display module and a display device, aiming at solving the problem of reducing the reflection of external ambient light on the display module.

In a first aspect of the present application, a display module is provided. The display module includes a substrate, a light-emitting device layer and a shielding layer, wherein the light-emitting device layer is arranged on a side of the substrate; the shielding layer is arranged on a side of the light-emitting device layer away from the substrate; and the shielding layer includes at least one shielding sublayer in a direction perpendicular to the substrate.

In a second aspect, an embodiment of the present application also provides a display device, including the display module of any one of the above embodiments.

The display module according to the embodiment of the present application includes a substrate, a light-emitting device layer and a shielding layer, wherein the shielding layer includes at least one shielding sublayer in a direction perpendicular to the substrate. The at least one shielding sublayer can absorb ambient light to reduce the reflectivity of external ambient light; and the shielding sublayer can also improve the display contrast and achieve a narrow-viewing-angle effect of the display module.

### BRIEF DESCRIPTION OF THE DRAWINGS

FIG. 1 is a schematic cross-sectional view of a display module according to an embodiment of the present application;

FIG. 2 is another schematic cross-sectional view of the display module according to an embodiment of the present application;

FIG. 3 is still another schematic cross-sectional view of the display module according to an embodiment of the present application;

FIG. 4 is yet another schematic cross-sectional view of the display module according to an embodiment of the present application;

FIG. 5 is a partial schematic view of the display module according to an embodiment of the present application;

FIG. 6 is another schematic cross-sectional view of the display module according to an embodiment of the present application;

FIG. 7 is still another schematic cross-sectional view of the display module according to an embodiment of the present application;

FIG. 8 is another partial schematic view of the display module according to an embodiment of the present application;

FIG. 9 is another schematic cross-sectional view of the display module according to an embodiment of the present application;

FIG. 10 is still another schematic cross-sectional view of the display module according to an embodiment of the present application;

FIG. 11 is yet another schematic cross-sectional view of the display module according to an embodiment of the present application; and

FIG. 12 is a further schematic cross-sectional view of the display module according to an embodiment of the present application.

### LIST OF REFERENCE SIGNS

100. Display module; 10. Substrate; 20. Light-emitting device layer; 21. Pixel defining layer; 22. Pixel opening; 23. Light-emitting unit; 30. Shielding layer; 31. Shielding sublayer; 32. Light shielding portion; 33. Light transmitting opening; 34. Reflecting portion; 40. Encapsulation layer; 41. First encapsulation sublayer; 42. Second encapsulation sublayer; 43. Third encapsulation sublayer; 50. Reflection control layer; 60. Cover plate; 70. Optical adhesive layer; 80. Touch layer; 81. Insulation layer; 82. Touch electrode.

### DETAILED DESCRIPTION OF EMBODIMENTS

Since ambient light is reflected on a surface of a display module, the visibility of a screen is reduced, and the content displayed on the screen is unclear and difficult to observe. Especially in outdoor or high-brightness environments, the reflection of external light reduces the visibility of the display module, and affects the display effect of the display module. Moreover, due to the extremely high reflectivity of a metal trace, an anode, etc. inside the display module, there may be a problem of high overall reflectivity of the display module.

In order to solve the above problems, embodiments of the present application provide a display module and a display device. Various embodiments of the display module, a method for preparing the display module and the display device will be described below with reference to the accompanying drawings.

An embodiment of the present application provides a display module. The display module may be an organic light emitting diode (OLED) display module, or the display module may be other types of display modules, for example, a micro light emitting diode (Micro-LED) or quantum light emitting diode (QLED) display module.

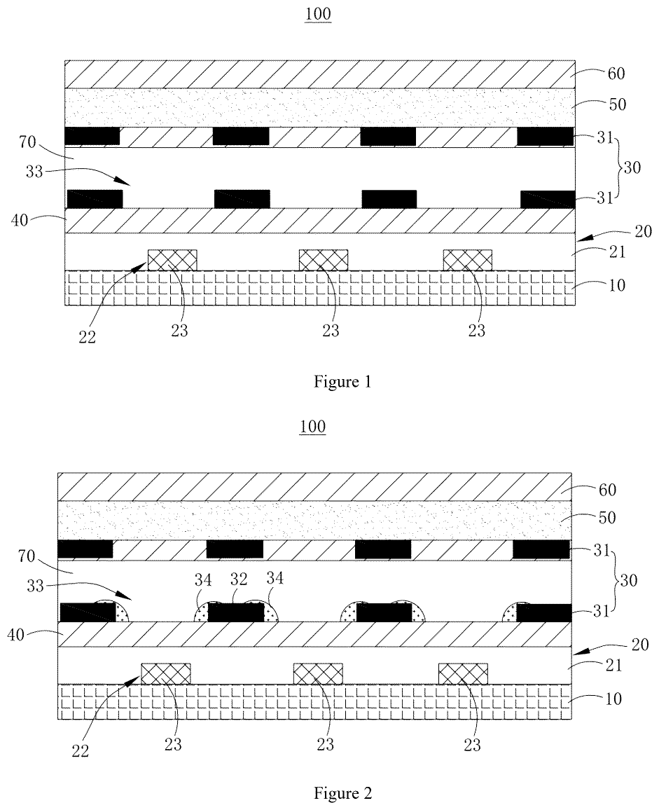

As shown in FIG. 1, in a first aspect of the present application, a display module 100 is provided. The display module 100 includes a substrate 10, a light-emitting device layer 20 and a shielding layer 30. The light-emitting device layer 20 is arranged on a side of the substrate 10. The shielding layer 30 is arranged on a side of the light-emitting device layer 20 away from the substrate 10. The shielding layer 30 includes at least one shielding sublayer 31 in a direction perpendicular to the substrate 10.

The substrate 10 includes a substrate base and an array layer. The substrate base may be a flexible substrate base made of polyimide (PI), polyethylene terephthalate (PET), and other materials to make the display module 100 bendable, or may be a rigid substrate base made of glass, ceramics and other materials. A drive circuit for controlling a light-emitting layer to emit light is arranged in the array layer. The array layer is generally composed of inorganic film layers such as a metal layer, a semiconductor layer (active layer) and an insulation layer. The drive circuit for controlling the light-emitting layer to emit light may be formed by patterning these inorganic film layers, and there may be various implementations of the specific circuit structure of the drive circuit, which will not be described in detail herein.

The light-emitting device layer 20 includes a first electrode (not shown), a light-emitting unit 23 and a second electrode (not shown) which are sequentially stacked in a direction away from the substrate 10. The first electrode, the light-emitting unit 23 and the second electrode are stacked in sequence to form a sub-pixel. The light-emitting unit 23 may be formed by stacking a plurality of film layer structures. By way of example, the light-emitting unit 23 may include a hole inject layer (HIL), a hole transport layer (HTL), a light-emitting layer, an electron inject layer (EIL) and an electron transport layer (ETL). The first electrode may be an anode, and the second electrode may be a cathode. When the first electrode and the second electrode are energized, electrons and holes migrate from the electron transport layer and the hole transport layer to the light-emitting layer respectively, and meet in the light-emitting layer to form excitons that excite light-emitting molecules, thereby generating visible light for the purpose of display.

Each shielding sublayer 31 of the shielding layer 30 may include a black matrix. The shielding sublayer 31 can absorb external ambient light to reduce the reflection of the external ambient light and can also absorb reflected light from a metal trace, an anode, etc. inside the display module 100 to reduce the reflectivity inside the display module 100. Moreover, the shielding sublayer 31 can also improve the display contrast and absorb large-viewing-angle light to achieve a narrow-viewing-angle effect of the display module 100, so as to adapt to certain application scenarios that do not require a large light-emitting angle, such as mobile phones, laptop computers or vehicle-mounted instruments that need to protect privacy. It should be noted that “large viewing angle” refers to a side viewing angle that deviates greatly from a front viewing angle, and for example, deviates from the front viewing angle by 30° to 89°.

Optionally, the shielding layer 30 includes a plurality of shielding sublayers 31, for example, two shielding sublayers 31, in the direction perpendicular to the substrate 10. Each shielding sublayer 31 is provided with a light transmitting opening 33 for emission of light from the light-emitting unit 23, such that the external ambient light, if not absorbed by the upper shielding sublayer 31, will be absorbed when irradiated into the lower shielding sublayer 31 through the light transmitting hole of the upper shielding sublayer 31. As opposed to providing only one shielding sublayer 31, providing the plurality of shielding sublayers 31 can further reduce the reflectivity of ambient light and can also further improve the narrow-viewing-angle effect.

In some embodiments, the light-emitting device layer 20 includes a pixel defining layer 21 and a plurality of light-emitting units 23. The pixel defining layer 21 has a plurality of pixel openings 22, and the light-emitting units 23 are located in the pixel openings 22.

The pixel defining layer 21 may include an inorganic material or a polymer material. For example, an inorganic material such as silicon oxide, silicon nitride and silicon may be used, or a polyimide polymer material may be used. The plurality of light-emitting units 23 and the plurality of pixel openings 22 may be arranged in one-to-one correspondence, or the light-emitting units 23 may be arranged corresponding to one pixel opening 22, thereby reducing mutual interference between the sub-pixels.

Preferably, each shielding sublayer 31 is provided with a plurality of light transmitting openings 33. An orthographic projection of the light transmitting opening 33 on the substrate 10 at least partially overlaps with an orthographic projection of the pixel opening 22 on the substrate 10.

The light transmitting opening 33 is located above the pixel opening 22, one light transmitting opening 33 is provided above each pixel opening 22, and the light transmitting opening 33 is filled with a light transmitting material such as an optical adhesive, such that light from the light-emitting unit 23 can exit through the light transmitting opening 33.

Optionally, a filter member, such as a filter plate and other optical devices for selecting desired radiation wavebands, may also be arranged in the light transmitting opening 33. The color of the filter member corresponds to the luminous color of the light-emitting unit 23 below the filter member. For example, the filter member above the red light-emitting unit 23 is a red filter member, which absorbs green light and blue light and allows only red light to exit; the filter member above the green light-emitting unit 23 is a green filter member, which absorbs red light and blue light and allows only green light to exit; and the filter member above the blue light-emitting unit 23 is a blue filter member, which absorbs red light and green light and allows only blue light to exit. By setting the filter member above each of the light-emitting units 23 of different luminous colors to have the same color as the luminous color of the light-emitting unit, the emission of stray light from the display module 100 can be reduced and the display effect can be improved.

Preferably, the orthographic projection of the pixel opening 22 on the substrate 10 is within the orthographic projection of the light transmitting opening 33 on the substrate 10.

The opening size of the light transmitting opening 33 is greater than the opening size of the pixel opening 22, i.e., the area of the orthographic projection of the light transmitting opening 33 on the substrate 10 is greater than the area of the orthographic projection of the pixel opening 22 on the substrate 10, such that light from the light-emitting unit 23 can be emitted from the display module 100 at a certain angle of inclination, achieving the narrow-viewing-angle effect.

As shown in FIG. 2, preferably, each shielding sublayer 31 includes a plurality of light shielding portions 32 and reflecting portions 34. The light transmitting openings 33 are formed between the light shielding portions 32, and each of the reflecting portions 34 is arranged on a side of a respective light shielding portion 32 close to a respective light transmitting opening 33.

The reflecting portion 34 may cover an edge of the light shielding portion 32, and there is a contact interface between the reflecting portion 34 and the light transmitting material or the filter member in the light transmitting opening 33. The light from the light-emitting unit 23 may be reflected from the contact interface, such that large-viewing-angle light to be absorbed by the light shielding portion 32 is converted into narrow-viewing-angle light, thereby improving the light output efficiency of the display module 100 and reducing the power consumption of the display module 100.

By way of example, the reflecting portion 34 is made of a material with a low refractive index, such as polyimide, polymethyl methacrylate, fluoropolymer and other organic materials. Since the light transmitting material or the filter member in the light transmitting opening 33 generally has a high refractive index, total reflection occurs at the contact interface between the reflecting portion 34 and the light transmitting material or the filter member in the light transmitting opening 33 without absorption by the light shielding portion 32, thereby converting the large-viewing-angle light into the narrow-viewing-angle light.

In some embodiments, the display module 100 further includes a reflection control layer 50 for absorbing part of ambient light. The reflection control layer 50 is arranged on a side of the light-emitting device layer 20 away from the substrate 10.

The reflection control layer 50 may be designed as an integral layer and may include a light absorbing material, such that when the ambient light enters the interior of the display module 100, the reflection control layer 50 can absorb part of the ambient light, but the reflection control layer 50 does not affect the emission of light from the light-emitting unit 23, minimizing loss of the light output efficiency.

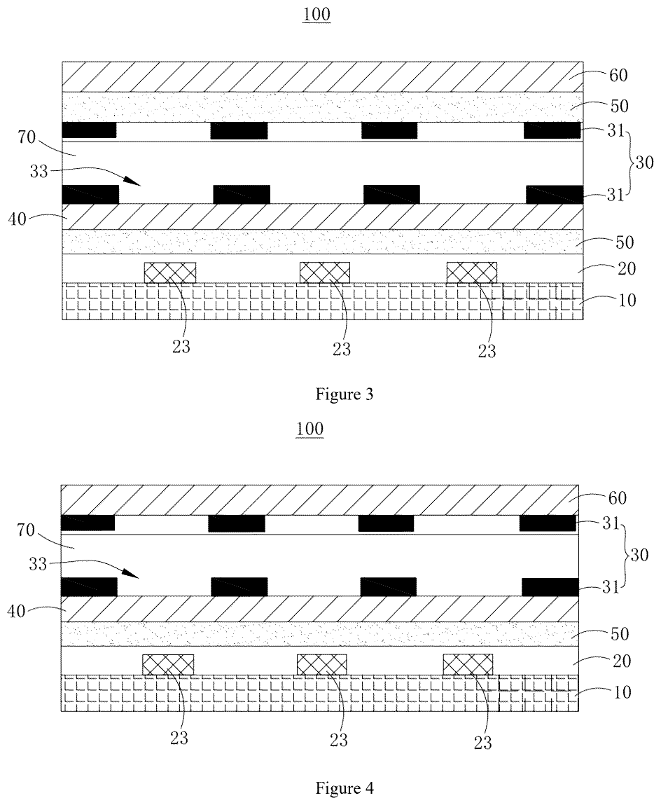

As shown in FIGS. 1 and 2, the shielding layer 30 may be arranged below the reflection control layer 50. As shown in FIG. 3, the shielding layer 30 may alternatively be arranged above the reflection control layer 50. Alternatively, as shown in FIG. 4, the shielding layer 30 may be arranged inside the reflection control layer 50.

As shown in FIG. 3, preferably, there are at least two reflection control layers 50, adjacent reflection control layers 50 being arranged at an interval.

For example, there may be two reflection control layers 50, and other film layers may be arranged between the two reflection control layers 50. The reflection of the ambient light can be further reduced by providing the multiple reflection control layers 50.

Preferably, the shielding layer 30 is located between two of the reflection control layers 50.

The ambient light may be partially absorbed by the upper reflection control layer 50, and the ambient light at certain angles may also be absorbed by the shielding layer 30. The ambient light at certain angles that is not absorbed by the shielding layer 30 continues to be partially absorbed upon entering the next reflection control layer 50, thereby enabling a more significant reduction in the reflection of the ambient light.

Of course, in other embodiments, the position of the reflection control layer 50 may be flexibly adjusted. For example, one reflection control layer 50 may be arranged between the shielding sublayers 31 of the shielding layer 30, and then a further reflection control layer 50 may be additionally arranged above or below the shielding layer 50, which may be selected flexibly according to requirements.

Preferably, the display module 100 further includes an encapsulation layer 40. The encapsulation layer 40 is arranged on the side of the light-emitting device layer 20 away from the substrate 10, and the shielding layer 30 is arranged on a side of the encapsulation layer 40 away from the substrate 10.

The encapsulation layer 40 covers the light-emitting device layer 20 for protecting the light-emitting device layer 20 from being corroded and damaged by water vapor and oxygen. The encapsulation layer 40 may be a thin-film encapsulation layer and, for example, may include an inorganic encapsulation layer, an organic encapsulation layer, and an inorganic encapsulation layer which are stacked, in order to achieve the effect of blocking moisture and oxygen.

Optionally, when there are at least two reflection control layers 50, all the reflection control layers 50 may be arranged above the encapsulation layer 40, or all of them may be arranged below the encapsulation layer 40. It is also possible to arrange some of the reflection control layers 50 above the encapsulation layer 40 and the other reflection control layers 50 below the encapsulation layer 40. Alternatively, it is also possible to arrange one of the reflection control layers 50 inside the encapsulation layer 40 and the other reflection control layers 50 above or below the encapsulation layer 40.

Preferably, a spacing between the shielding layer 30 and the encapsulation layer 40 is defined as L, where L meets the following condition: 15 μm≤L≤1 mm. Optionally, the spacing L between the shielding layer 30 and the encapsulation layer 40 may be 50 μm, 100 μm, 500 μm or 800 μm.

It should be noted that L refers to the spacing between the shielding layer 30 and the middle position of the encapsulation layer 40. For example, if the shielding layer 30 includes a plurality of shielding sublayers 31, and the encapsulation layer 40 includes an inorganic encapsulation layer, an organic encapsulation layer, and an inorganic encapsulation layer which are stacked, L refers to the spacing between the uppermost shielding sublayer 31 and the organic encapsulation layer of the encapsulation layer 40.

In the embodiments of the present application, the spacing between the shielding layer 30 and the encapsulation layer 40 is defined such that a suitable spacing can exist between the shielding layer 30 and the light-emitting device layer 20. If the spacing between the shielding layer 30 and the encapsulation layer 40 is too small, the shielding layer 30 is too close to the light-emitting device layer 20, so that the light-emitting unit 23 may still have a large light-emitting viewing angle and the narrow-viewing-angle effect cannot be achieved. If the spacing between the shielding layer 30 and the encapsulation layer 40 is too large, the shielding layer 30 is too far away from the light-emitting device layer 20, resulting in an extremely narrow viewing angle of the light-emitting unit 23 and greatly reducing the light output efficiency. In the embodiments of the present application, the spacing between the shielding layer 30 and the encapsulation layer 40 is within a suitable range, which can not only achieve the narrow-viewing-angle effect, but can also reduce loss of the light output efficiency.

Preferably, the display module 100 further includes a cover plate 60. The cover plate 60 is arranged on a side of the shielding layer 30 away from the substrate 10.

The cover plate 60 may be a glass cover plate for protecting the display module 100 against scratches, impacts or other physical damages, helping to prolong the service life of the display module 100 and maintain its good appearance. The cover plate 60 can prevent dust, fingerprints and other contaminants from adhering to the surface of the display module 100, thereby keeping an image clear. The cover plate 60 can also increase the overall strength of the display module 100.

In the conventional display module 100, light from the light-emitting unit 23 needs to pass through a polarizer during the process of exiting a screen, and its emergent light is linearly polarized light. Moreover, the transmittance of the polarizer is less than 50%, which results in a decrease in the light output efficiency of the display module 100. However, in the embodiments of the present application, the polarizer is omitted, and the cover plate 60 is arranged directly on the shielding layer 30, so that the emergent light does not have the polarization characteristic, which makes human eyes more comfortable and also improves the light output efficiency of the display module 100.

In some embodiments, the reflection control layer 50 includes a light absorbing material.

The light absorbing material may absorb part of the ambient light. The ambient light is irradiated into the display module 100 after the polarizer is removed, and thanks to the presence of reflective film layers such as a cathode and an anode, the reflectivity of the display module 100 will increase to some extent. In the embodiments of the present application, since the display module 100 is provided with the shielding layer 30 and the reflection control layer 50, the reflection control layer 50 absorbs light in some wavebands after the ambient light is irradiated into the display module 100, such that the ambient light is attenuated after irradiated into the display module 100. Moreover, by means of the patterned shielding layer 30, the ambient light at a certain angle is partially absorbed by the light shielding portion 32 between different light-emitting units 23.

Preferably, the light absorbing material includes a color paste. A transmittance of the color paste to light emitted by the light-emitting units 23 is greater than a transmittance of the color paste to light in other wavebands.

The color paste may selectively transmit light. For example, the color paste may have high transmittance for the emitted light wavebands of the red light-emitting unit 23, the green light-emitting unit 23 and the blue light-emitting unit 23 but low transmittance for other wavebands between the light wavebands of the light-emitting units 23 of different colors.

It should be noted that in the embodiments of the present application, the “color paste” does not contain a solvent, but is a material that remains after a raw material mixture of the color paste is added with a solvent and the solvent is evaporated and removed after coating.

Preferably, the reflection control layer 50 further includes a light transmitting material. By way of example, the light transmitting material may include a resin such as polycarbonate and polyamide. The light absorbing material may be added to the light transmitting material, or the color paste may be added to the light transmitting material, or both of the light absorbing material and the color paste may be added to the light transmitting material. The light transmitting material can further improve the light output efficiency of the display module 100.

Preferably, the light absorbing material includes at least one of powdered carbon, black masterbatch, copper, iron, zinc, copper oxide, iron oxide and zinc oxide.

The light absorbing material may be a material specifically selected according to the location where the reflection control layer 50 is arranged. For example, if the reflection control layer 50 is arranged above the encapsulation layer 40, or if the reflection control layer 50 is arranged inside the encapsulation layer 40, the light absorbing material may be selected from powdered carbon and black masterbatch with high light absorption coefficients, so as to absorb the ambient light by using the powdered carbon and black masterbatch. If the reflection control layer 50 is arranged below the encapsulation layer 40, the light absorbing material may be selected from at least one of copper, iron, zinc, copper oxide, iron oxide and zinc oxide. The metals or metal oxides described above achieve a reduction in reflectivity by using the principle of destructive interference.

Preferably, the color paste includes at least one of porphyrazine compounds, porphyrin compounds, metalloporphyrin compounds, oxazine compounds, squaraine compounds, triarylmethane compounds, polymethine compounds, anthraquinone compounds, phthalocyanine compounds, azo compounds, perylene compounds, xanthene compounds, diammonium compounds, dipyrromethene compounds and cyanine compounds.

The materials of the color paste described above can further improve the light output efficiency of the light-emitting unit 23 of each color and reduce the transmittance of light in other wavebands.

As shown in FIG. 4, in some embodiments, the reflection control layer 50 is arranged between the light-emitting device layer 20 and the encapsulation layer 40.

The light-emitting device layer 20, the reflection control layer 50, the encapsulation layer 40 and the shielding layer 30 are sequentially arranged on the substrate 10. A part of the ambient light that is not absorbed by the shielding layer 30 is further absorbed by the reflection control layer 50 after entering the display module 100, thereby reducing the reflectivity. The reflection control layer 50 can also selectively increase the transmittances of the red light-emitting unit 23, the green light-emitting unit 23 and the blue light-emitting unit 23.

Preferably, the reflection control layer 50 includes a light absorbing material. The light absorbing material includes at least one of copper, iron, zinc, copper oxide, iron oxide and zinc oxide.

In the embodiments of the present application, the reflection control layer 50 is located below the encapsulation layer 40, and at least one of copper, iron, zinc, copper oxide, iron oxide and zinc oxide reduces the reflectivity by using the principle of destructive interference.

Specifically, destructive interference is an optical phenomenon based on the characteristics of two or more light waves when they interfere with each other. When the two light waves meet, their amplitudes may increase to form a new resultant wave. If these light waves have opposite phases and the same amplitude, they will cancel each other out, causing the intensity of the light to decrease or disappear completely. When the light absorbing material of at least one of copper, iron, zinc, copper oxide, iron oxide and zinc oxide is added to the reflection control layer 50, the phases and the amplitudes of the light waves absorbed by these materials are opposite to the phases and the amplitudes of the transmitted light waves. When these light waves meet again, they will be subjected to destructive interference, resulting in a decrease in the reflectivity of the light.

As shown in FIG. 6, in some embodiments, the encapsulation layer 40 includes a first encapsulation sublayer 41, a second encapsulation sublayer 42, and a third encapsulation sublayer 43 which are sequentially arranged in a direction away from the substrate 10. The encapsulation effect of the display module 100 can be improved by superposition of the three thin-film encapsulation sublayers 41,42 and 43.

Preferably, each of the first encapsulation sublayer 41 and the third encapsulation sublayer 43 includes an inorganic material, and the second encapsulation sublayer 42 includes an organic material.

By way of example, the first encapsulation sublayer 41 and the third encapsulation sublayer 43 may be made of a material such as silicon oxide, silicon nitride or silicon oxynitride, which can provide good mechanical support and encapsulation protection to prevent the display module 100 from being affected by the environment. Moreover, the first encapsulation sublayer 41 and the third encapsulation sublayer 43 can also effectively insulate external harmful substances such as moisture and oxygen from entering the display module 100, thereby prolonging the service life and improving the stability of the display module 100. The second encapsulation sublayer 42 may be made of an organic material such as a polymer. The second encapsulation sublayer 42 has a thickness greater than that of the first encapsulation sublayer 41 and that of the third encapsulation sublayer 43, is more flexible, and thus can better adapt to the bending and curvature of the display module 100. In addition, the organic material can also serve to buffer an external force.

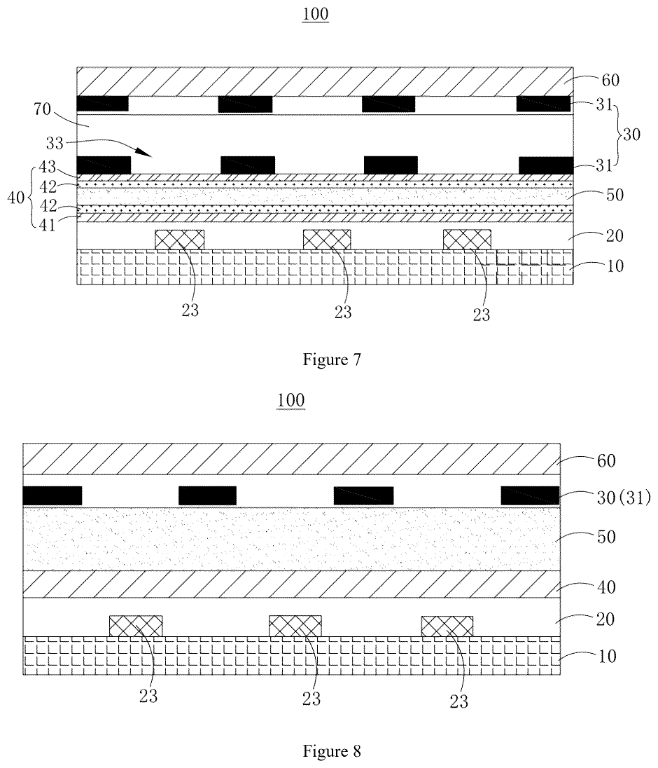

As shown in FIG. 7, in some other embodiments, the reflection control layer 50 is arranged in the second encapsulation sublayer 42.

Preferably, the reflection control layer 50 includes a light absorbing material. The light absorbing material includes at least one of copper, iron, zinc, copper oxide, iron oxide and zinc oxide.

In the embodiments of the present application, the reflection control layer 50 is located in the second encapsulation sublayer 42, and the light absorbing material selected from at least one of copper, iron, zinc, copper oxide, iron oxide and zinc oxide reduces the reflectivity by using the principle of destructive interference.

As shown in FIG. 8, in some other embodiments, the reflection control layer 50 is arranged on the side of the encapsulation layer 40 away from the substrate 10.

The light-emitting device layer 20, the encapsulation layer 40 and the reflection control layer 50 are sequentially arranged on the substrate 10. The reflection control layer 50 is located above the encapsulation layer 40, and the reflection control layer 50 can not only reduce the reflectivity but can also reduce loss of the light output efficiency.

Preferably, the reflection control layer 50 includes a light absorbing material. The light absorbing material includes at least one of powdered carbon and black masterbatch.

In the embodiments of the present application, since the reflection control layer 50 is arranged above the encapsulation layer 40, and powdered carbon or black masterbatch having a high absorption coefficient is selected as the light absorbing material in the reflection control layer 50, when the ambient light is irradiated onto the surfaces of these materials, the materials can absorb most of the energy of light without reflection or transmission.

As shown in FIG. 1, preferably, the reflection control layer 50 is arranged on the side of the shielding layer 30 away from the substrate 10.

The light-emitting device layer 20, the encapsulation layer 40, the shielding layer 30 and the reflection control layer 50 are sequentially arranged on the substrate 10. After entering the interior of the display module 100, the ambient light is first partially absorbed by the reflection control layer 50. Then, when the remaining ambient light continues to enter the interior, the light may be partially absorbed again by the shielding layer 30, thereby reducing the reflectivity. The reflection control layer 50 can also selectively increase the transmittances of the red light-emitting unit 23, the green light-emitting unit 23 and the blue light-emitting unit 23.

Referring to FIGS. 1-4 and 7, preferably, the shielding layer 30 includes at least two shielding sublayers 31, and the display module 100 further includes an optical adhesive layer 70. The optical adhesive layer 70 is arranged between adjacent shielding sublayers 31.

An optical adhesive is filled between the adjacent shielding sublayers 31, and the optical adhesive layer 70 can not only improve the light output efficiency of display module 100 but can also increase the spacing between the adjacent shielding sublayers 31, such that the shielding layer 30 can absorb more ambient light. Part of the large-angle ambient light, if not absorbed by the upper shielding sublayer 31, may be absorbed by the lower shielding sublayer 31 after passing through the optical adhesive layer 70 with a certain thickness.

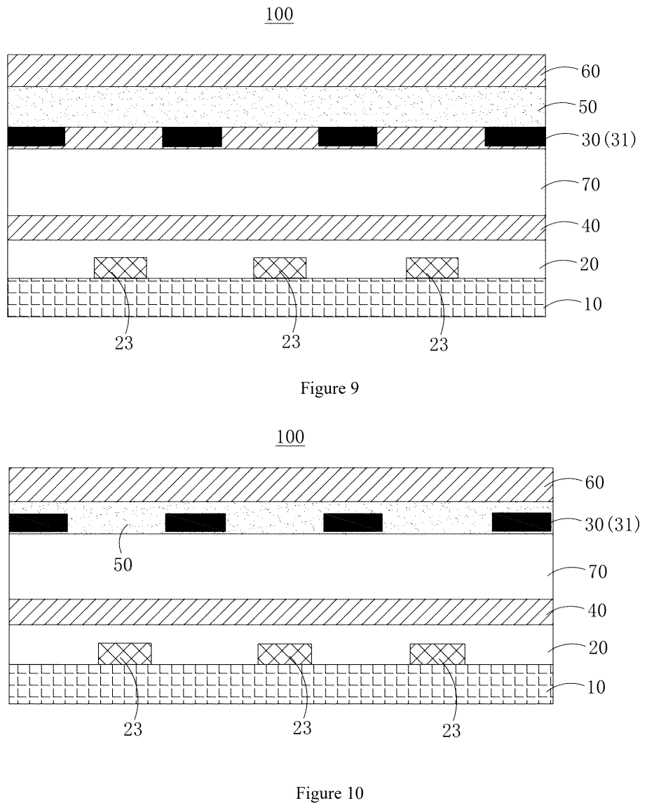

Alternatively, referring to FIGS. 9 and 10, in some other embodiments, the shielding layer 30 includes one shielding sublayer 31, and the display module 100 further includes an optical adhesive layer 70. The shielding sublayer 31 is arranged on a side of the optical adhesive layer 70 away from the substrate 10.

In the embodiments of the present application, the shielding layer 30 is provided with only one shielding sublayer 31. The light-emitting device layer 20, the encapsulation layer 40, the optical adhesive layer 70 and the shielding sublayer 31 are sequentially arranged on the substrate 10. The optical adhesive layer 70 increases the spacing between the light-emitting device layer 20 and the shielding sublayer 31, such that more large-viewing-angle light of the light-emitting unit 23 can be absorbed by the shielding sublayer 31, thereby improving the narrow-viewing-angle effect of the display module 100.

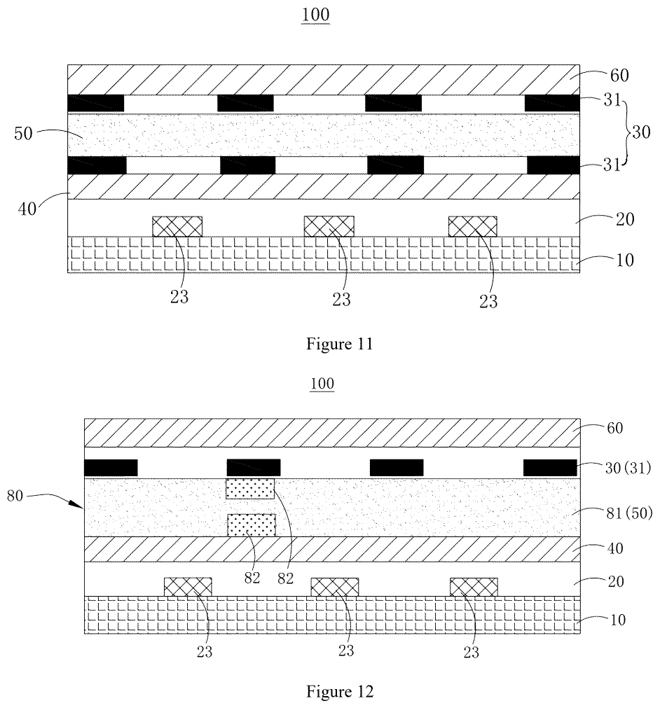

In some embodiments, as shown in FIG. 11, the shielding layer 30 includes at least two shielding sublayers 31, and the reflection control layer 50 is arranged between adjacent shielding sublayers 31.

By way of example, a first patterned shielding sublayer 31 is first prepared on the encapsulation layer 40, a light transmitting opening 33 of the shielding sublayer 31 is filled with an optical adhesive, then a reflection control layer 50 is prepared, and a second patterned shielding sublayer 31 is then prepared on the reflection control layer 50.

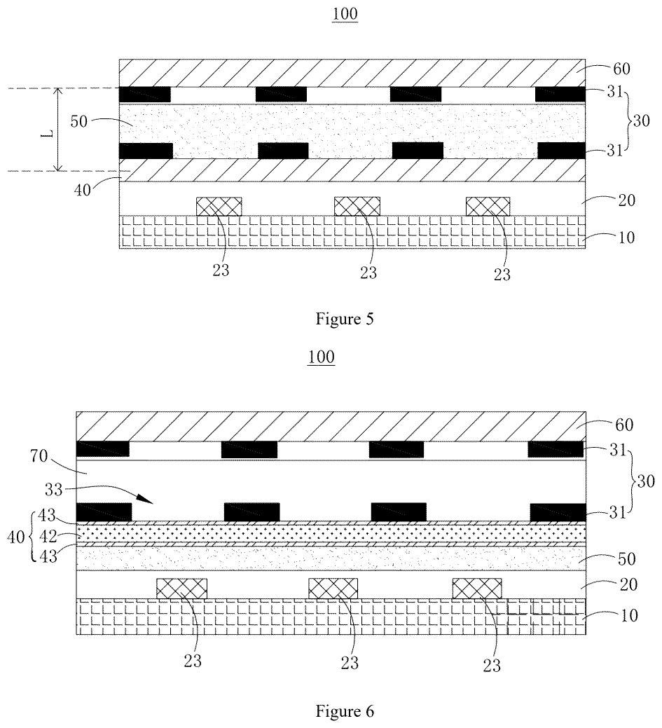

Alternatively, as shown in FIG. 5, in some other embodiments, the shielding layer 30 includes at least two shielding sublayers 31. At least one of the shielding sublayers 31 is arranged in the reflection control layer 50, and the reflection control layer 50 covers the at least one of the shielding sublayers 31.

By way of example, a first patterned shielding sublayer 31 is first prepared on the encapsulation layer 40, a reflection control layer 50 is then prepared, a light transmitting opening 33 of the first shielding sublayer 31 is filled with the material of the reflection control layer 50, and a second patterned shielding sublayer 31 is then prepared on the reflection control layer 50.

Alternatively, as shown in FIG. 1, in still other embodiments, the shielding layer 30 includes at least two shielding sublayers 31, and the shielding layer 30 is arranged on a side of the reflection control layer 50 away from the substrate 10.

The light-emitting device layer 20 and the encapsulation layer 40 are first sequentially arranged on the substrate 10, the shielding layer 30 is then prepared on the encapsulation layer 40, and the reflection control layer 50 is then prepared on the shielding layer 30. The light transmitting opening 33 of the uppermost shielding sublayer 31 may be filled with either the optical adhesive or the material of the reflection control layer 50.

As shown in FIG. 12, in some embodiments, the display module 100 further includes a touch layer 80. The touch layer 80 is arranged between the encapsulation layer 40 and the cover plate 60, and the touch layer 80 includes an insulation layer 81 and a touch electrode 82 arranged in the insulation layer 81.

The touch layer 80 is a transparent layer for receiving a touch input from a user, such that touch interaction and input can be achieved, allowing the user to control the display device by directly touching the screen. The touch electrode 82 is an electrode structure arranged inside the insulation layer 81 of the touch layer 80 and serves to detect and respond to a touch operation of the user. The insulation layer 81 in the touch layer 80 may serve to isolate a touch input signal, and when the user touches the screen, the touch input signal (e.g., a charge) will be sensed and transmitted to the touch layer 80. The insulation layer 81, through its insulating property, limits the touch input signal to a specific area to avoid false conduction and interference of the signal. Owing to the presence of the insulation layer 81, the touch sensitivity can also be improved, and the touch input signal is prevented from excessive diffusion and leakage, such that the touch layer can detect and interpret the user's touch motion more accurately. In a capacitive touch screen, the insulation layer 81 also helps to reduce mutual capacitive interference. When multiple touch points exist at the same time, the insulation layer 81 can prevent current from interfering between different touch areas, improving the accuracy and the reliability of multi-point touch. The insulation layer 81 also helps to ensure proper transmission of the touch input signal, which provides a reliable dielectric environment to prevent loss of charges and electric leakage, ensuring that the touch layer can accurately sense and interpret the touch input.

Preferably, the reflection control layer 50 is reused as the insulation layer 81.

Reusing the reflection control layer 50 as the insulation layer 81 of the touch layer 80 can facilitate process preparation and reduce the cost.

Preferably, the shielding layer 30 is arranged on a side of the touch layer 80 away from the substrate 10.

The arrangement of the shielding layer 30 above the touch layer 80 can reduce the influence of the external ambient light on the touch layer 80, thereby improving the touch sensitivity.

In a second aspect, an embodiment of the present application also provides a display device, including the display module 100 of any one of the above embodiments. The display device employs all the technical solutions of all the above embodiments, and therefore has at least all the beneficial effects brought by the technical solutions of the above embodiments, which will not be described in detail herein.

The display device may be any device with a display function, for example, a mobile device, such as a mobile phone, a tablet computer, a laptop computer, a palmtop computer, a vehicle-mounted electronic device, a wearable device, an ultra-mobile personal computer (UMPC), a netbook, or a personal digital assistant (PDA), or a non-mobile device, such as a personal computer (PC), a television (TV), a teller machine, or a self-service machine.

The foregoing descriptions are merely specific implementations of the present application, but are not intended to limit the protection scope of the present application. Any equivalent modification or replacement readily figured out by a person skilled in the art within the technical scope disclosed in the present application shall fall within the protection scope of the present application. Therefore, the scope of protection of the present application shall be subject to the scope of protection of the claims.

What is claimed is:

1. A display module, comprising:
a substrate;
a light-emitting device layer arranged on a side of the substrate; and
a shielding layer arranged on a side of the light-emitting device layer away from the substrate, wherein the shielding layer comprises at least one shielding sublayer in a direction perpendicular to the substrate.

2. The display module according to claim 1, wherein the light-emitting device layer comprises a pixel defining layer and a plurality of light-emitting units, the pixel defining layer having a plurality of pixel openings, and the light-emitting units being located in the pixel openings.

3. The display module according to claim 2, wherein each shielding sublayer is provided with a plurality of light transmitting openings, an orthographic projection of the light transmitting opening on the substrate at least partially overlapping with an orthographic projection of the pixel opening on the substrate.

4. The display module according to claim 3, wherein the orthographic projection of the pixel opening on the substrate is within the orthographic projection of the light transmitting opening on the substrate.

5. The display module according to claim 3, wherein each shielding sublayer comprises a plurality of light shielding portions and a plurality of reflecting portions, the light transmitting openings being formed between the light shielding portions, and each of the reflecting portions being arranged on a side of a respective light shielding portion close to a respective light transmitting opening.

6. The display module according to claim 2, further comprising at least one reflection control layer for absorbing part of ambient light, wherein the reflection control layer is arranged on the side of the light-emitting device layer away from the substrate;
there are at least two reflection control layers, adjacent reflection control layers being arranged at an interval;
the shielding layer is located between two of the reflection control layers.

7. The display module according to claim 6, wherein the display module further comprises an encapsulation layer, the encapsulation layer being arranged on the side of the light-emitting device layer away from the substrate, and the shielding layer being arranged on a side of the encapsulation layer away from the substrate;
a spacing between the shielding layer and the encapsulation layer is defined as L, where L meets the following condition: 15 μm≤L≤1 mm.

8. The display module according to claim 7, wherein the display module further comprises a cover plate, the cover plate being arranged on a side of the shielding layer away from the substrate.

9. The display module according to claim 6, wherein the reflection control layer comprises a light absorbing material.

10. The display module according to claim 9, wherein the light absorbing material comprises at least one of powdered carbon, black masterbatch, copper, iron, zinc, copper oxide, iron oxide and zinc oxide.

11. The display module according to claim 9, wherein the light absorbing material comprises a color paste, a transmittance of the color paste to light emitted by the light-emitting units being greater than a transmittance of the color paste to light in other wavebands; the color paste comprises at least one of porphyrazine compounds, porphyrin compounds, metalloporphyrin compounds, oxazine compounds, squaraine compounds, triarylmethane compounds, polymethine compounds, anthraquinone compounds, phthalocyanine compounds, azo compounds, perylene compounds, xanthene compounds, diammonium compounds, dipyrromethene compounds and cyanine compounds.

12. The display module according to claim 9, wherein the reflection control layer further comprises a light transmitting material.

13. The display module according to claim 7, wherein the reflection control layer is arranged between the light-emitting device layer and the encapsulation layer; and
the reflection control layer comprises a light absorbing material, the light absorbing material comprising at least one of copper, iron, zinc, copper oxide, iron oxide and zinc oxide.

14. The display module according to claim 7, wherein the encapsulation layer comprises a first encapsulation sublayer, a second encapsulation sublayer, and a third encapsulation sublayer which are sequentially arranged in a direction away from the substrate;
each of the first encapsulation sublayer and the third encapsulation sublayer comprises an inorganic material, and the second encapsulation sublayer comprises an organic material;
the reflection control layer is arranged in the second encapsulation sublayer; and
the reflection control layer comprises a light absorbing material, the light absorbing material comprising at least one of copper, iron, zinc, copper oxide, iron oxide and zinc oxide.

15. The display module according to claim 7, wherein the reflection control layer is arranged on the side of the encapsulation layer away from the substrate;
the reflection control layer is arranged on the side of the shielding layer away from the substrate;
the shielding layer comprises at least two shielding sublayers, and the display module further comprises an optical adhesive layer, the optical adhesive layer being arranged between adjacent shielding sublayers;
or the shielding layer comprises one shielding sublayer, and the display module further comprises an optical adhesive layer, the shielding sublayer being arranged on a side of the optical adhesive layer away from the substrate.

16. The display module according to claim 15, wherein the reflection control layer comprises a light absorbing material, the light absorbing material comprising at least one of powdered carbon and black masterbatch.

17. The display module according to claim 6, wherein the shielding layer comprises at least two shielding sublayers, the reflection control layer being arranged between adjacent shielding sublayers;
or at least one of the shielding sublayers is arranged in the reflection control layer, and the reflection control layer covers the at least one of the shielding sublayers;
or the shielding layer is arranged on a side of the reflection control layer away from the substrate.

18. The display module according to claim 8, further comprising a touch layer, wherein the touch layer is arranged between the encapsulation layer and the cover plate, and the touch layer comprises an insulation layer and a touch electrode arranged in the insulation layer;
the reflection control layer is reused as the insulation layer.

19. The display module according to claim 18. wherein preferably, the shielding layer is arranged on a side of the touch layer away from the substrate.

20. A display device, comprising a display module according to claim 1.
